(19) United States
(12) Patent Application Publication
(10) Pub. No.: US 2026/0298973 A1
(43) Pub. Date: Oct. 1, 2026

(54) BATTERY TEST BENCH AND SYSTEM FOR TESTING BATTERIES

(71) Applicant: ZF Friedrichshafen AG, Friedrichshafen (DE)

(72) Inventors: Alexander DENK, Hohenau (DE); Nico RUTZHOFER, Hauzenberg (DE)

(73) Assignee: ZF Friedrichshafen AG, Friedrichshafen (DE)

(21) Appl. No.: 19/578,321

(22) Filed: Mar. 25, 2026

(30) Foreign Application Priority Data
Mar. 26, 2025 (DE) 10 2025 111 626.1

(51) Int. Cl. G01R 1/04; G01R 31/36; G01R 31/364

(52) U.S. Cl. CPC G01R 1/0408; G01R 31/364; G01R 31/3644

(57) ABSTRACT

A battery test bench (100) for testing batteries (200, 201) has a test cell (110), at least two electric power sources (120, 121), and at least four current rails (130, 131, 132, 133). Each electric power source (120, 121) is designed to supply an electric voltage and to deliver an electric current. The current rails (130, 131, 132, 133) are designed for the electrical connection of the electric power sources (120, 121) in each case with a respective battery (200, 201) to be tested. The test cell (110) is designed to accommodate and arrange the current rails (130, 131, 132, 133). The battery test bench (100) also has at least one rail bridge (150, 155) designed to connect a battery (200, 201) simultaneously to the electric power sources (120, 121), so that the electric power sources (120, 121) are connected in parallel.

### RELATED APPLICATIONS

This application claims the benefit of and right of priority under 35 U.S.C. § 119 to German Patent Application no. 10 2025 111 626.1, filed on 26 Mar. 2025, the contents of which are incorporated herein by reference in its entirety.

### FIELD OF THE DISCLOSURE

The invention relates to a battery test bench for testing batteries and to a corresponding system.

### BACKGROUND

In the prior art it is known to equip motor vehicles with completely electric-motor-powered drives or with a so-termed hybrid drive. In that case, a battery, also called the traction battery, serves to supply an electric motor or several electric motors with electrical energy in order to drive the motor vehicle by means of the one or more electric motors. During the manufacture of such batteries, they are subjected to a variety of tests. Among other things a test of the battery performance is carried out, which ensures its functionality and functional reliability as part of an end-of-line testing procedure. For that purpose, a battery to be tested is charged and discharged again repeatedly, for example over a short period of time.

In the context of these performance tests, it is important for reliable connections for the transfer of electrical power to be made so as to connect the battery being tested to the testing equipment. For that purpose, it is known, for example, for each pole of a battery to be provided with a push-in type connector with an individual pin and with an individual contact socket, wherein the contacting can be monitored for example by thermosensors or other types of sensors.

In this connection, a battery test bench and a method for testing a battery cell are known from DE 10 2020 118 231 A1. The battery test bench comprises a holder for receiving a battery cell, an electric charging device which is electrically connected to the battery cell, and a device for detecting volume changes of the battery cell.

DE 10 2013 012 219 B3 discloses a battery test bench for testing at least two batteries. For that purpose, the battery test bench comprises a battery tester, a protective device with at least a first and a second switch position, and a control unit for controlling the protective device. In its first switch position, the protective device is designed to connect a first battery to the battery tester and to disconnect a second battery from the battery tester. In its second switch position, the protective device is designed to connect the second battery to the battery tester and to disconnect the first battery from the battery tester.

From EP 2 544 295 A1 a battery test bench is known, which comprises a test cell in which a battery to be tested is arranged, a holder which is arranged in the test cell and can receive the battery, a control unit that can be connected to a battery arranged in the holder, at least one sensor device for monitoring the battery, the sensor device being connected to the control unit, and a cooling device which is connected with the control unit and which is designed to cool the battery in the test cell in the event that a hazardous situation should arise.

### SUMMARY

However, the known battery test benches have the disadvantage that they cannot be adapted to varying test requirements, or only so to a very small extent.

A purpose of the present invention is to propose an improved battery test bench for the testing of batteries.

According to the invention, this objective is achieved by the battery test bench for testing batteries. Advantageous design features are described herein.

The invention relates to a battery test bench for testing batteries, in particular high-voltage batteries, such as those used in electric vehicles.

For that purpose the battery test bench comprises a test cell, at least two sources of electrical power, and at least four current rails, wherein the at least two power sources are designed in each case to supply an electric voltage and to deliver an electric current, whereas the at least four current rails are designed to connect electrically the at least two electric power sources, respectively, with one of the batteries to be tested in each case, and wherein the test cell is designed to receive and arrange the at least four current rails.

Thus, the invention relates to a battery test bench for the testing, in particular, of batteries for electric vehicles or other electric storage means.

As described, the battery test bench comprises, among other things, a test cell in which, preferably, all the current rails and all the electric contacts to or from the current rails are accommodated. Thus, the test cell ensures that accidents, due to unintentional contact of the operating personnel of the test bench with parts of the test bench which are electrically ‘live’ (voltage-carrying), can be avoided.

Furthermore, the test bench can comprise other elements as well, such as a controlled-climate chamber, an air-conditioning unit, switch cabinets, sensors, and one or more control units.

Advantageously, no electrically ‘live’ (voltage-carrying) parts of the battery test bench can be accessed from outside the test bench.

In this case, the at least four current rails, respectively in pairs, provide a plus path and a minus path in each case for a battery to be tested, in order to connect the battery to be tested electrically with one of the power sources.

Thus, for example, the battery test bench can test two batteries at the same time, each of the two batteries being connected to a respective power source.

According to the invention, it is now provided that the battery test bench comprises at least one rail bridge, wherein the at least one rail bridge is designed to connect an individual battery simultaneously to the at least two electric power sources, so that the at least two electric power sources are connected in parallel.

Thus, an advantage of the invention is that by virtue of the parallel connection of the power sources by the rail bridge, flexible adaptation of the test conditions to various batteries or various test conditions is made possible. In particular, thanks to the parallel connection, large test currents can be produced without being obliged to have recourse to special, particularly powerful power sources. This both reduces investment costs and also increases the scalability and adaptability of the test bench to differing requirements.

Thus, all-in-all, a more flexible, safer, and more efficient battery test bench is provided, which is designed to meet a variety of testing requirements.

In an advantageous embodiment of the invention, it is provided that the at least one rail bridge has a plus path and a minus path, wherein the plus path and the minus path are held and spaced apart from one another by a connecting element made of a non-conducting material.

Particularly preferably, it is provided that the non-conducting material is a plastic.

Here, the connecting element serves not only for mechanical fixing, but at the same time also ensures reliable electrical insulation between the current paths. This on the one hand increases electrical safety and on the other hand ensures exact positioning of the plus and minus paths relative to one another.

Besides, the connecting element simplifies the assembly of a parallel-connected rail unit, since the paths are already pre-positioned and assembly errors are therefore minimized.

In a further advantageous embodiment of the invention, it is provided that the at least one rail bridge has a defined pattern of apertures, such that a first lot of the apertures are designed to enable contact with the at least four current rails at their contact points and such that a second lot of the apertures are designed as contact points for electrical connection with a battery to be tested.

An advantage of this embodiment is that by virtue of the defined pattern of apertures a clear and unambiguous association of the connections between the rail bridge and the current rails is ensured. In that way, the risk of erroneous connections is to a large extent excluded, which in turn improves both the safety and the reliability of the testing process. The defined pattern of apertures also reduces the time spent on fitting and assembly work.

According to a further advantageous embodiment of the invention, it is provided that by virtue of the first lot of apertures, the at least one rail bridge can be screwed to the contact points of the at least four current rails.

This embodiment offers the advantage that a stable mechanical connection is provided, which ensures reliable electrical contact.

At the same time, the screwing enables simple fitting and dismantling of the rail bridge, so that refitting work can be carried out quickly and without complication.

In a further advantageous embodiment of the invention, it is provided that the test cell has guide bolts for positioning the at least one rail bridge.

The use of such guide bolts offers advantages for the assembly and refitting work, since they enable the rail bridge to be positioned quickly, precisely and without error.

According to a further advantageous embodiment of the invention, it is provided that the battery test bench comprises two additional current rails, each of which has a larger cross-sectional area than that of the aforesaid at least four current rails, the two additional current rails being designed to be electrically connected to a total of two power sources.

These additional current rails are specially designed to be connected not just with one, but with two power sources. This gives the advantage that, for example, the two additional current rails enable a battery to be tested using double the power of a single power source.

Thanks to the larger cross-sectional area of the additional current rails particularly large electric currents can be transmitted safely, whereby tests with large current strengths—for example using two power sources connected in parallel—can be carried out.

In this case it is equally possible for the two power sources to be associated with one and the same battery test bench, or for the power sources to be associated completely or partially with another battery test bench.

Thus, an advantage of this embodiment is that it enables the simple and secure extension or cascading of the battery test bench.

Namely, the additional current rails also allow a simple mechanical and electric coupling of a plurality of battery test benches with one another. This makes it possible to adapt the testing capacities flexibly for varying requirements, without any need for extensive and time-consuming conversion measures.

In a further advantageous embodiment of the invention it is provided that the battery test bench comprises an additional rail bridge, wherein the additional rail bridge is designed to connect the battery additionally to further power sources of the further test bench in such manner that the at least two electric power sources and the further power sources are connected in parallel.

This enables a connection in parallel of the at least two electric power sources of the battery test bench with further power sources of other battery test benches, so that the current strength available for the testing process is again increased considerably.

Thus, an advantage of this embodiment is also that by virtue of the additional rail, bridge large testing currents can be produced without being obliged to have recourse to other, more powerful and expensive power sources.

The additional rail bridge contributes essentially to the scalability and flexibility of the battery test bench. It makes it possible to react quickly and simply to changing requirements and test conditions.

According to a further advantageous embodiment of the invention, it is provided that the additional rail bridge has a defined pattern of apertures, such that a first lot of the apertures are designed to enable the contacting of the two additional current rails at their contact points, whereas a second lot of the apertures are designed to enable the contacting of the at least one rail bridge, and whereas a third lot of the apertures are designed as contact points for electrical connection with a battery to be tested.

An advantage of this embodiment is that thanks to the clearly defined and specially arranged pattern of apertures, a clear association of the electrical connections, which precludes confusion, is achieved. This considerably reduces the risk of assembly errors, short-circuits or wrong connections during the conversion of the test bench.

In addition, this design favors a simple and quick adaptation of the battery test bench to varying requirements relating to different test scenarios or test conditions, since it is clearly established which components are to be connected, and in what manner. This increases flexibility and reduces possible sources of error during operation.

In a further advantageous embodiment of the invention, it is provided that the additional rail bridge can be screwed to the contact points of the two additional current rails by virtue of the first lot of apertures and can be screwed to the contact points of the at least one rail bridge by virtue of the second lot of apertures.

An advantage of this embodiment is also in this case that the ability to screw through defined apertures results in particularly reliable, mechanically stable and secure electrical connections. This not only ensures reliable electrical contacting with low transfer resistance, but also prevents the inadvertent undoing or loosening of the connections during operation.

According to a further advantageous embodiment of the invention, it is provided that the test cells comprise guide bolts for positioning the additional rail bridge.

An advantage of this design is that the guide bolts enable the additional rail bridge to be positioned quickly and precisely. This considerably facilitates assembly and effectively avoids assembly errors that could result in faulty electrical connections or mechanical instability.

In a further advantageous embodiment of the invention, it is provided that the battery test bench has a first switch such that the first switch is designed to be actuated automatically when the at least one rail bridge is positioned correctly, and/or that the battery test bench has a second switch such that the second switch is designed to be actuated automatically when the additional rail bridge is positioned correctly, and when the first switch is actuated a blockage of the at least two electric power sources is eliminated and when the second switch is actuated a blockage of the further power sources is eliminated.

An advantage of this embodiment is that thanks to the automated actuation of the switches, reliable and direct verification of the correct assembly configuration is ensured. This enhances the operational safety, since an erroneous configuration is recognized and the electric power sources are automatically blocked in order to prevent damage to the equipment and hazard to the operating personnel.

Furthermore, the automated switch actuation contributes toward shortening maintenance and assembly times, since there is no need for manual checking or additional verification that assembly is correct. This results in overall improved efficiency of the test bench, shorter idle times and less conversion effort and cost.

According to a further advantageous embodiment of the invention, it is provided that the battery test bench comprises voltage measurement-section devices, which are designed to detect voltage measurement values of the at least four current rails and of the at least one parallel rail unit, and/or voltage measurement values of the two further current rails and the additional parallel rail unit, and if unexpected voltage measurement values are observed, to block the at least two electric power sources and/or to block the further power sources.

An advantage of this embodiment is that by virtue of the continual monitoring of the voltage values, a direct and reliable recognition of unexpected operating conditions is made possible. Thereby, potential fault conditions such as faulty connections, short-circuits or unacceptable voltage deviations are recognized promptly, and the electric power sources are automatically blocked. This also increases the safety of the test bench and thus improves the protection of the test objects connected to it and of the operating personnel.

Moreover, the voltage measurement-section device enables a precise diagnosis and location of fault sources, whereby maintenance work is also speeded up and simplified. Thanks to the automated detection and evaluation of the measurement values, faults can be automatically recognized and eliminated, and this reduces idle times and improves the overall availability of the battery test bench.

Furthermore, this design improves the documentation and tracking of the testing process, since all the relevant voltage data are detected continuously and precisely. This enables a detailed analysis and optimization of the testing procedure.

In a further advantageous embodiment of the invention, it is provided that the battery test bench has a transparent protective cover which, after an access door has been opened, covers all the current-carrying components to prevent contact and which has finger-contact-safe apertures in order to enable voltage measurements to be made in the secure condition.

An advantage of this embodiment is that safety for the operating personnel is increased. Thanks to the transparent design of the protective cover the current-carrying components can be inspected visually at any time, without direct contact being possible. This reduces the risk of electrical accidents.

The finger-contact-safe apertures also enable safe voltage measurement without having to remove the protective cover. This not only improves working safety, but also facilitates maintenance and diagnostic work, since the necessary tests can be carried out safely and quickly.

The invention also relates to a system for testing batteries. The system according to the invention is characterized in that it involves at least two battery test benches according to the invention.

This results in the advantages already described.

A further advantage is also that by using more than one battery test bench, a large number of batteries or complex battery arrangements can be tested efficiently and in parallel at the same time. This reduces the total duration of the testing process and therefore increases the productivity and efficiency of the testing sequences.

Furthermore, the power sources of several battery test benches can be connected in parallel so as to test a battery using particularly high powers.

According to a further advantageous embodiment of the invention, it is provided that the at least two battery test benches are made identically.

The use of identical test benches in the system offers advantages in relation to modularity, unification and standardization.

Moreover, the identical design of the battery test benches enables the system as a whole to be extended quickly and without complications, since new battery test benches can be added and integrated without problems. This scalability ensures great flexibility when testing conditions vary and offers the possibility of enlarging capacities for short periods and without major adaptations.

### BRIEF DESCRIPTION OF THE DRAWINGS

Below, examples of the invention are explained with reference to embodiments illustrated in the figures, which show:

FIG. 1: As an example and schematically, a battery test bench according to the invention for testing batteries,

FIG. 2: An example of a rail bridge,

FIG. 3: As an example, the battery test bench 100 of FIG. 1 but with the rail bridge mounted in the test cell,

FIG. 4: As an example, a possible embodiment of a system according to the invention for testing batteries, and

FIG. 5: An example of an additional rail bridge.

### DETAILED DESCRIPTION

The same objects, functional units and comparable components are denoted by the same indexes in all the figures. These objects, functional units and comparable components are made identically as regards their technical characteristics unless otherwise indicated explicitly or implicitly in the description.

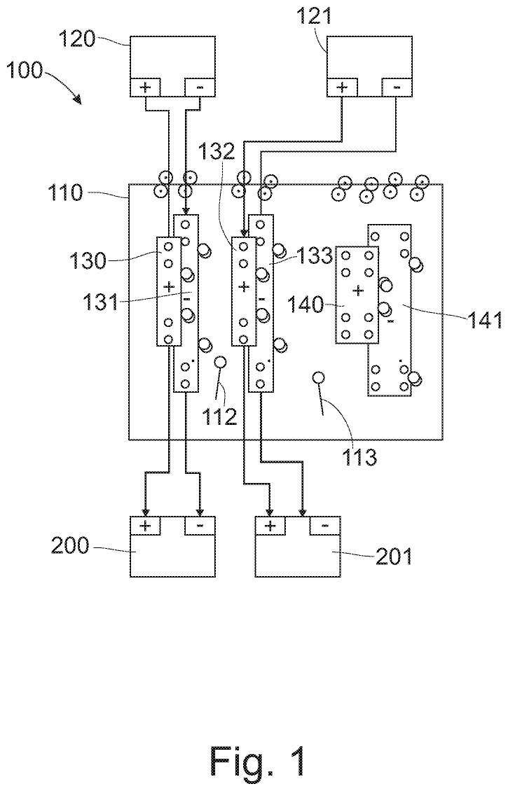

FIG. 1 shows an example, represented schematically, of a battery test bench 100 according to the invention for the testing of batteries 200, 201.

In this example, the battery test bench 100 in FIG. 1 comprises a test cell 110, two electric power sources 120, 12,1 and four current rails 130, 131, 132, 133. In this case the four current rails 130, 131, 132, 133 are arranged inside the test cell 110 and are therefore screened relative to the surroundings. Since the current rails 130, 131, 132, 133 can carry high electric voltages and large electric currents, the current rails 130, 131, 132, 133 basically constitute a hazard for the operating personnel of the battery test bench 100.

In this example, the test cell 110 also has a transparent protective cover (not shown in FIG. 1), which covers all the current-carrying components, thereby preventing contact with them even after an access door (also not shown in FIG. 1) has been opened.

The two electric power sources 120, 121 are in the form of DC voltage or current sources 120, 121, and each supplies a voltage and a current with which charging processes and discharging processes of the batteries 200, 201 can be carried out.

In this example, each power source 120, 121 can deliver an electric current of up to 1000 A. Basically, however, it is also possible for a power source 120, 121 to be designed to deliver a higher or a lower current.

The four current rails 130, 131, 132, 133 serve to connect the two electric power sources 120, 121 electrically, in each case, to one of the batteries 200 201 to be tested, and in this example the rails are made of copper.

In each case, a current rail 130, 132 connects a plus pole of a power source 120, 121 to a plus pole, of a battery 200, 201 to be tested. The respective other current rail 131, 133 connects a minus pole of a power source 120, 121 to a minus pole of a battery 200, 201 to be tested.

As can also be seen, the battery test bench 100 has two additional current rails 140, 141, which are also arranged inside the test cell 110. These additional current rails 140, 141 also consist of copper in this example, but each has a larger cross-sectional area than the four current rails 130, 131, 132, 133.

Accordingly, the additional current rails 140, 141 are suitable for transporting larger electric currents and can at the same time be connected to the two power sources 120, 121.

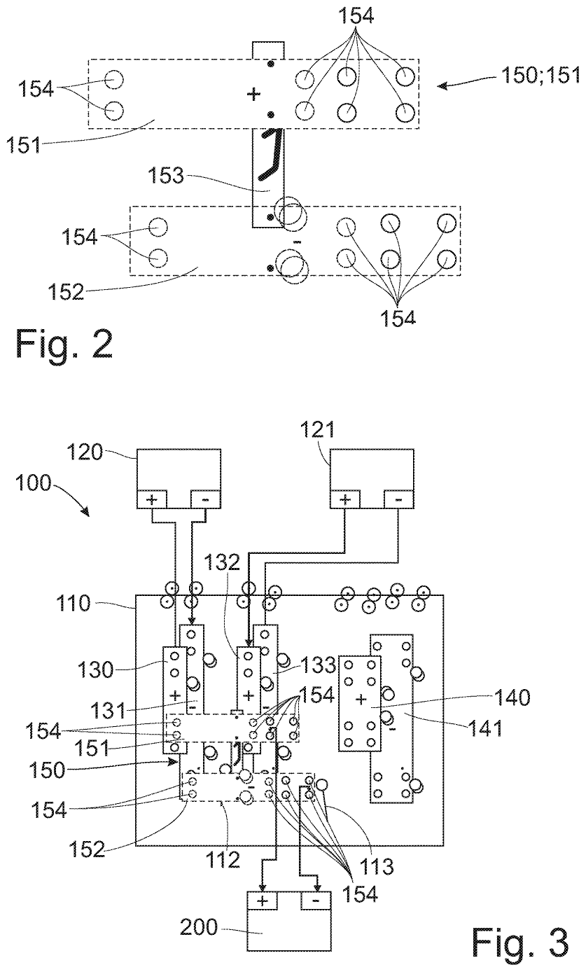

The battery test bench 100 also comprises a rail bridge 150, shown in FIG. 2, which, however, is not fitted in the representation shown in FIG. 1.

The rail bridge 150 is designed to connect one of the two batteries 120, 121 simultaneously to the two electric power sources 120, 121, so that the two electric power sources 120, 121 are connected in parallel.

The rail bridge 150 has a plus path 151 and a minus path 152, such that the plus path 151 and the minus path 152 are held by a connecting element 153 made of a non-conducting material and are a distance apart from one another. In this example, the non-conducting material is a plastic.

As can also be seen, the rail bridge 150 has a defined pattern of apertures 154, wherein a first lot of the apertures 154 are designed for the contacting of the four current rails 130, 131, 132, 133 at their contact points and wherein a second lot of the apertures 154 are designed as contact points for the electrical connection of the batteries 200, 201 to be tested.

In this example, the rail bridge 150 can be screwed, through the first lot of apertures 154, to the current rails 130, 131, 132, 133.

The test cell 110 also has guide bolts for the positioning of the current rails 130, 131, 132, 133 and the rail bridge 150.

In addition, in the test cell 110 the battery test bench 100 comprises a first switch 112 and a second switch 113, which are designed to be actuated automatically when the at least one rail bridge has been positioned correctly.

When the first switch 112 is actuated by the rail bridge 150, a blockage of the two electric power sources 120, 121 is eliminated so that a testing process by means of the two electric power sources 120, 121 can take place. This ensures that the testing process can only take place if the rail bridge 150 is correctly fitted and the first switch 112 has been actuated. In the selected operating mode illustrated in FIG. 1 the second switch 113 does not have to be actuated.

FIG. 3 shows the battery test bench 100 of FIG. 1, but with the rail bridge 150 fitted in the test cell 110. As can be seen, the plus path 151 connects the two positive current rails 130, 132 to one another and the minus path 152 connects the two negative current rails 131, 133 to one another. Thus, by virtue of the second lot of apertures 154, which form contact points for electrical connection with the battery 200 to be tested, the two power sources 120 121 are connected to a single battery 200 with the power sources 120, 121 connected in parallel. Accordingly, the battery 200 can be tested using double the current strength, for example 2000 A.

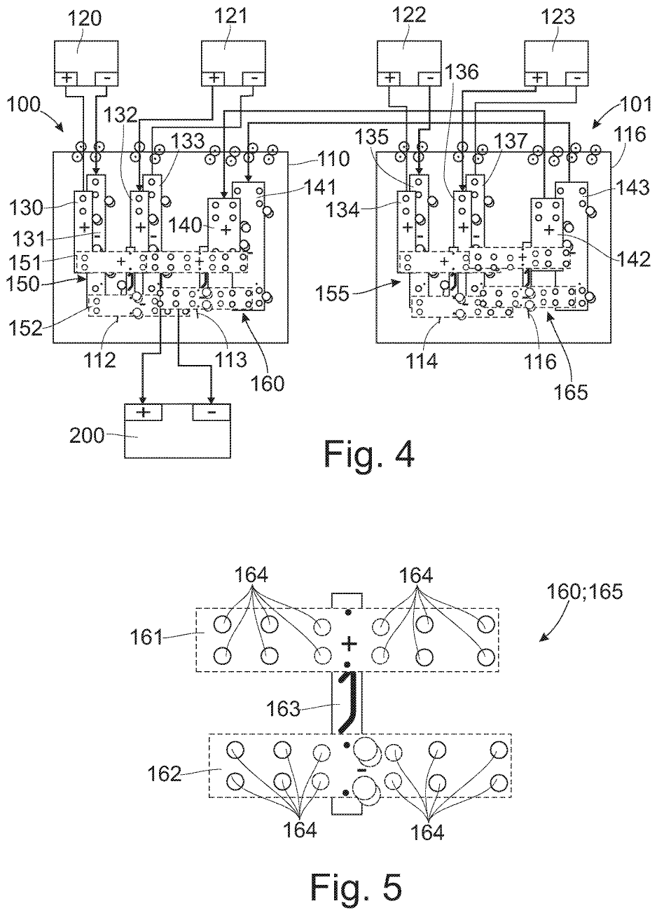

FIG. 4 shows as an example a possible embodiment of a system 300 according to the invention for the testing of batteries 200, 201, which system comprises a battery test bench 100 and a further battery test bench 101, the further battery test bench 101 being made identically to the battery test bench 100.

As can be seen, a respective rail bridge 150, 151 is fitted in each of the battery test benches 100, 101.

Furthermore, in each case, an additional rail bridge 160, 161 is fitted. These additional rail bridges 160, 161 are different from the rail bridges 150, 151 and make it possible for the further power sources 122, 123 of the further battery test bench 101 to be connected in parallel with the two power sources 120, 121 of the battery test bench 100, so that the battery 200 to be tested can in theory be tested with four times the electric current produced by the individual power sources 120, 121, 122, 123.

In the selected operating mode shown in FIG. 4, both the two first switches 112, 114 and also the two second switches 113, 115 have to be actuated in order to eliminate a blockage of the two power sources 120, 121 and of the two further power sources 122, 123.

The first switches 112, 114 are actuated automatically when the rail bridges 150, 155 are fitted correctly. The second switches 113, 115 are actuated automatically when the additional rail bridges 160, 165 are fitted correctly.

An additional rail bridge 160 is shown as an example in FIG. 5. As can be seen, the additional rail bridge 160 also has a defined pattern of apertures 164, such that a first lot of the apertures 164 are designed for enabling contact with the two additional current rails 140, 141 at their contact points, whereas a second lot of apertures 164 are designed for contacting the at least one rail bridge 150, 155 and whereas a third lot of apertures 164 are designed for the electrical contacting of the battery 200 to be tested.

The additional rail bridge 160 has a plus path 161 and a minus path 162, and the plus path 161 and the minus path 162 are held a distance apart from one another by a connecting element 163 made of a non-conducting material.

In this example, the additional rail bridges 160, 165 can be screwed via the first lot of apertures 164 to the additional current rails 140, 141 or 142, 143 respectively. Via the second lot of apertures 164 the additional rail bridges 160, 165 can be screwed to the current rails 130, 131, 132, 133 or 134, 135, 136, 137 respectively.

The test cell 110 also has guide bolts for positioning the additional rail bridge 160.

Analogously, the test cell 116 has guide bolts for positioning the current rails 134, 135, 136, 137, the rail bridge 155 and the additional rail bridge 165.

### Indexes

100 Battery test bench
101 Further battery test bench
110 Test cell (of the battery test bench 100)
112 First switch (in the test cell 110)
113 Second switch (in the test cell 110)
114 First switch (in the test cell 116 of the further battery test bench 101)
115 Second switch (in the test cell 116 of the further battery test bench 101)
116 Test cell (of the further battery test bench 101)
120. 121 Electric power sources (DC voltage and current sources)
122, 123 Further electric power sources (DC voltage and current sources of the battery test bench (101)
130, 131, 132, 133 Current rails (in the test cell 110)
134, 135, 136, 137 Current rails (in the test cell 116)
140, 141 Additional current rails (in the test cell 110, with larger cross-sectional areas)
142, 142 Additional current rails (in the test cell 116, with larger cross-sectional areas)
150, 155 Rail bridges
151 Plus path of the rail bridge 150
152 Minus path of the rail bridge 150
153 Connection element (made of non-conducting material, for positioning the plus and minus paths)
154 Apertures (in the rail bridge 150, for contacting the current rails and batteries)
160, 161, 165 Additional rail bridges
161 Plus path of the additional rail bridge 160
162 Minus path of the additional rail bridge 160
163 Connection element (made of non-conducting material, for positioning the plus and minus paths of the additional rail bridge 160)
164 Apertures (in the additional rail bridge 160 for contacting the additional current rails, rail bridges and batteries)
200, 201 Batteries
300 System for testing batteries (comprising the battery test benches 100 and 101)

1. A battery test bench (100) for testing batteries (200, 201), comprising:
a test cell (110);
at least two electric power sources (120, 121); and
at least four current rails (130, 131, 132, 133), and
at least one rail bridge (150, 155) configured to connect a battery (200, 201) simultaneously to the at least two electric power sources (120, 121), so that the at least two electric power sources (120, 121) are connected in parallel:
wherein the at least two electric power sources (120, 121) are each configured to supply an electric voltage and to deliver an electric current, and
wherein the at least four current rails (130, 131, 132, 133) are configured for the electrical connection of the at least two electric power sources (120, 121) each to a respective battery (200, 201) to be tested,
wherein the test cell (110) is configured to accommodate and arrange the at least four current rails (130, 131, 132, 133).

2. The battery test bench (100) according to claim 1, wherein the at least one rail bridge (150, 155) has a plus path (151) and a minus path (152), and the plus path (151) and the minus path (152) are spaced a distance apart from one another by a connecting element (153) made of a non-conducting material.

3. The battery test bench (100) according to claim 2, wherein the at least one rail bridge (150, 155) has a defined pattern of apertures (154), such that a first lot of the apertures (154) are configured to enable contact with the at least four current rails (130, 131, 132, 133) at their contact points and such that a second lot of the apertures (154) are configured as contact points for electrical connection with one of the batteries (200, 201) to be tested.

4. The battery test bench (100) according to claim 3, wherein the at least one rail bridge (150, 155) is configured to be screwed through the first lot of apertures (154) to the contact points of the at least four current rails (130, 131, 132, 133).

5. The battery test bench (100) according to claim 4, wherein the test cell (110) has guide bolts for positioning the at least one rail bridge (150, 155).

6. The battery test bench (100) according to claim 1, comprising:
two additional current rails (140, 141), each having a cross-sectional area which is larger than those of the at least four current rails (130, 131, 132, 133), wherein the two additional current rails (140, 141) are configured to be electrically connected to a total of two power sources (120, 121).

7. The battery test bench (100) according to claim 1, comprising:
an additional rail bridge (160, 161, 165) configured to connect the battery (200, 201) additionally to further power sources (122, 123) of a further battery test bench (101), so that the at least two electric power sources (120, 121) and the further power sources (122, 123) are connected in parallel.

8. The battery test bench (100) according to claim 7, wherein the additional rail bridge (160, 161, 165) has a defined pattern of apertures (164), wherein a first lot of the apertures (164) are configured for contacting the two additional current rails (140, 141) at their contact points, wherein a second lot of the apertures (164) are configured for contacting the at least one rail bridge (150, 155), and wherein a third lot of the apertures (164) are configured as contact points for electrical connection with a battery (200, 201) to be tested.

9. The battery test bench (100) according to claim 8, wherein the additional rail bridge (160, 161, 165) is configured to be screwed through the first lot of the apertures (164) to the contact points of the two additional current rails (140, 141) and is configured to be screwed through the second lot of the apertures (164) to the contact points of the at least one rail bridge (150, 155).

10. The battery test bench (100) according to claim 8, wherein the test cell (110) has guide bolts for positioning the additional rail bridge (160, 161, 165).

11. The battery test bench (100) according to claim 8, comprising:
a first switch (112, 114) configured to be actuated automatically when the at least one rail bridge (150, 155) is in position, and/or
a second switch (113, 115) configured to be actuated automatically when the additional rail bridge (160, 161, 165) is in position, such that when the first switch (112, 114) is actuated, a blockage of the at least two electric power sources (120, 121) is eliminated and such that when the second switch (113, 115) is actuated a blockage of the further power sources (122, 123) is eliminated.

12. The battery test bench (100) according to claim 1, comprising:
voltage measurement-section devices configured to detect voltage measurement values of the current rails (130, 131, 132, 133, 140, 141) and of the at least one rail bridge (150, 155, 160, 161, 165), and configured to block the power sources (120, 121, 122, 123) if unexpected voltage measurement values are detected.

13. The battery test bench (100) according to claim 1, comprising a transparent protective cover which covers all current-carrying components to prevent contact with the current-carrying components after an access door has been opened, wherein the transparent protective cover defines finger-touch-safe apertures configured to enable voltage measurements to be made safely.

14. A system (300) for testing batteries, comprising at least two battery test benches (100, 101) according to claim 1.

15. The system according to claim 14, wherein the at least two battery test benches (100, 101) are identical.
